(19) United States
(12) Patent Application Publication
(10) Pub. No.: US 2023/0369086 A1
(43) Pub. Date: Nov. 16, 2023

(54) ANALYSIS APPARATUS AND ANALYSIS METHOD

(71) Applicant: FUJIFILM Corporation, Tokyo (JP)

(72) Inventors: Akihiko OHTSU, Shizuoka (JP); Masahiro YOSHIDOME, Shizuoka (JP); Yukihisa KAWADA, Shizuoka (JP); Ryo SAITO, Shizuoka (JP)

(73) Assignee: FUJIFILM Corporation, Tokyo (JP)

(21) Appl. No.: 18/357,183

(22) Filed: Jul. 24, 2023

Related U.S. Application Data
(63) Continuation of application No. PCT/JP21/45095, filed on Dec. 8, 2021.

(30) Foreign Application Priority Data
Jan. 26, 2021 (JP) 2021-010235
Feb. 26, 2021 (JP) 2021-029645

(51) Int. Cl. H01L 21/67; H01L 21/66; H01J 49/10; G01N 21/95

(52) U.S. Cl. CPC H01L 21/67288; H01L 22/12; H01J 49/105; G01N 21/9501

(57) ABSTRACT

Provided are an analysis apparatus and an analysis method capable of analyzing a smaller defect on a surface of a semiconductor substrate. An analysis apparatus includes a surface defect measurement unit that measures presence or absence of a defect on a surface of a semiconductor substrate, and obtains positional information on the surface of the semiconductor substrate for the defect on the surface of the semiconductor substrate, and an analysis section that performs inductively coupled plasma mass spectrometry by irradiating the defect on the surface of the semiconductor substrate with laser light based on the positional information of the defect on the surface of the semiconductor substrate, and collecting an analysis sample obtained by the irradiation using a carrier gas.

### CROSS-REFERENCE TO RELATED APPLICATIONS

This application is a Continuation of PCT International Application No. PCT/JP2021/045095 filed on Dec. 8, 2021, which claims priority under 35 U.S.C. § 119(a) to Japanese Patent Application No. 2021-010235 filed on Jan. 26, 2021 and Japanese Patent Application No. 2021-029645 filed on Feb. 26, 2021. The above applications are hereby expressly incorporated by reference, in their entirety, into the present application.

### BACKGROUND OF THE INVENTION

### 1. Field of the Invention

The present invention relates to an analysis apparatus and an analysis method of analyzing a defect on a surface of a semiconductor substrate by using a laser ablation-inductively coupled plasma mass spectrometry (LA-ICP-MS).

### 2. Description of the Related Art

At present, various semiconductor devices are manufactured using a semiconductor substrate, such as a silicon substrate. In a case in which there is a defect, such as a foreign substance, on a surface of the semiconductor substrate, a gate of a transistor may be insufficiently formed during the manufacture of the semiconductor device, or a wiring line may be broken, so that the manufactured semiconductor device may be a defective product. Such a defect, such as the foreign substance, on the surface of the semiconductor substrate influences a yield of the semiconductor device.

The defect of the semiconductor substrate can be evaluated by using, for example, a method of evaluating residual metal impurities inside a silicon crystal of a silicon wafer disclosed in JP2019-195020A. In the method of evaluating the residual metal impurities inside the silicon crystal of the silicon wafer in JP2019-195020A, heat treatment is performed, the metal impurities inside the silicon crystal are collected on a surface of the silicon wafer, and then vapor phase decomposition inductively coupled plasma mass spectrometry (VPD-ICP-MS) is performed to measure a concentration of the metal impurities collected on the surface of the silicon wafer. The number of surface defects of the silicon wafer is measured by using a SurfScan SP5 manufactured by KLA Corporation.

### SUMMARY OF THE INVENTION

In the vapor phase decomposition inductively coupled plasma mass spectrometry in JP2019-195020A, the silicon wafer is melted, and the defect of the semiconductor substrate cannot be evaluated in a non-destructive manner.

As a method of evaluating the defect of the semiconductor substrate in a non-destructive manner, there is a method of evaluating metal contamination of a wafer in JP2020-027920A.

In the method of evaluating the metal contamination of the wafer in JP2020-027920A, it is disclosed that, as a foreign substance examination device, a particle counter (for example, SurfScan SP5 manufactured by KLA Corporation) of a light scattering system that detects the foreign substance by scanning a wafer surface with laser light and measuring the light scattering intensity from the foreign substance, a laser microscope (for example, MAGICS manufactured by Lasertec Corporation) of a confocal optical system that detects the foreign substance by detecting a difference in reflected rays from the wafer surface, and the like are used. JP2020-027920A discloses that scanning electron microscope (SEM) observation of a bright spot is performed based on coordinates acquired in a first step, and energy dispersive X-ray spectroscopy (EDX) analysis is performed based on characteristic X-rays generated by electron beam irradiation.

Here, as described above, in a case in which there is the defect, such as the foreign substance, on the surface of the semiconductor substrate, in particular, as the miniaturization of the semiconductor device and the high integration of the semiconductor device progress, the defect on the surface of the semiconductor substrate generates the defective product of the semiconductor device, and the influence on the deterioration of the yield of the semiconductor device is increased. For this reason, it is important to measure the defect on the surface of the semiconductor substrate, and it is more important to measure a minute foreign substance among the defects of the semiconductor substrate. However, in a case in which the method of evaluating the metal contamination of the wafer disclosed in JP2020-027920A is used for analysis of the minute foreign substance having a size of about 20 nm on the surface of the semiconductor substrate, there is a high possibility that element analysis cannot be performed with the EDX. At present, there is a demand for a device capable of analyzing the minute foreign substance having a size of about 20 nm on the surface of the semiconductor substrate.

The present invention is to provide an analysis apparatus and an analysis method capable of analyzing a smaller defect on a surface of a semiconductor substrate.

In order to achieve the above-described object, one aspect of the present invention provides an analysis apparatus that uses positional information of a defect on a surface of a semiconductor substrate, the analysis apparatus comprising an analysis section that performs inductively coupled plasma mass spectrometry by irradiating the defect on the surface of the semiconductor substrate with laser light based on the positional information of the defect on the surface of the semiconductor substrate, and collecting an analysis sample obtained by the irradiation using a carrier gas.

Another aspect of the present invention provides an analysis apparatus comprising a surface defect measurement device that measures presence or absence of a defect on a surface of a semiconductor substrate, and obtains positional information of the defect on the surface of the semiconductor substrate, and a mass spectrometry device that performs inductively coupled plasma mass spectrometry by irradiating the defect on the surface of the semiconductor substrate with laser light based on the positional information of the defect on the surface of the semiconductor substrate obtained by the surface defect measurement device, and collecting an analysis sample obtained by the irradiation using a carrier gas.

It is preferable that the surface defect measurement device includes a storage unit that stores the positional information.

It is preferable that the surface defect measurement device includes an incidence unit that causes incidence rays to be incident on the surface of the semiconductor substrate, and a light receiving unit that receives radiated rays radiated by reflection or scattering of the incidence rays due to the defect on the surface of the semiconductor substrate.

Still another aspect of the present invention provides an analysis apparatus includes a surface defect measurement unit that measures presence or absence of a defect on a surface of a semiconductor substrate, and obtains positional information on the surface of the semiconductor substrate for the defect on the surface of the semiconductor substrate, and an analysis section that performs inductively coupled plasma mass spectrometry by irradiating the defect on the surface of the semiconductor substrate with laser light based on the positional information of the defect on the surface of the semiconductor substrate, and collecting an analysis sample obtained by the irradiation using a carrier gas.

It is preferable that the surface defect measurement unit includes a storage unit that stores the positional information.

It is preferable that the surface defect measurement unit includes an incidence unit that causes incidence rays to be incident on the surface of the semiconductor substrate, and a light receiving unit that receives radiated rays radiated by reflection or scattering of the incidence rays due to the defect on the surface of the semiconductor substrate.

It is preferable that the analysis apparatus further comprises a container portion that accommodates the semiconductor substrate that is a measurement target, in which an analysis of the semiconductor substrate by the analysis section is performed in the container portion.

It is preferable that the analysis apparatus further comprises a cleaning gas supply unit that supplies a cleaning gas to an inside of the container portion, and an outflow unit that allows the cleaning gas to flow out from the inside of the container portion.

It is preferable that the analysis apparatus further comprises an introduction portion in which an accommodation container that accommodates the semiconductor substrate that is a measurement target is installed, and a transport device that transports the semiconductor substrate from the introduction portion to the surface defect measurement unit.

Still another aspect of the present invention provides an analysis method in which positional information of a defect on a surface of a semiconductor substrate is used, the analysis method comprising a step of performing inductively coupled plasma mass spectrometry by irradiating the defect on the surface of the semiconductor substrate with laser light based on the positional information of the defect on the surface of the semiconductor substrate, and collecting an analysis sample obtained by the irradiation using a carrier gas.

Still another aspect of the present invention provides an analysis method comprising a step of measuring presence or absence of a defect on a surface of a semiconductor substrate, and obtaining positional information on the surface of the semiconductor substrate for the defect on the surface of the semiconductor substrate, and a step of performing inductively coupled plasma mass spectrometry by irradiating the defect on the surface of the semiconductor substrate with laser light based on the positional information of the defect on the surface of the semiconductor substrate, and collecting an analysis sample obtained by the irradiation using a carrier gas.

It is preferable that the carrier gas has a moisture content being equal to or more than 0.00001 ppm by volume and equal to or less than 0.1 ppm by volume.

It is preferable that the step of performing the inductively coupled plasma mass spectrometry is performed in a container portion that accommodates the semiconductor substrate that is a measurement target, and the analysis method further comprises a step of cleaning an inside of the container portion using a cleaning gas, which is performed before the step of performing the inductively coupled plasma mass spectrometry.

According to the present invention, it is possible to analyze the smaller defect on the surface of the semiconductor substrate.

### BRIEF DESCRIPTION OF THE DRAWINGS

FIG. 1 is a schematic view showing a first example of an analysis apparatus according to an embodiment of the present invention.

FIG. 2 is a schematic view showing an example of an analysis unit of the first example of the analysis apparatus according to the embodiment of the present invention.

FIG. 3 is a schematic view showing a first example of an analysis method according to the embodiment of the present invention.

FIG. 4 is a schematic cross-sectional view showing the first example of the analysis method according to the embodiment of the present invention.

FIG. 5 is a schematic view showing a second example of the analysis apparatus according to the embodiment of the present invention.

FIG. 6 is a schematic view showing a third example of the analysis apparatus according to the embodiment of the present invention.

FIG. 7 is a schematic view showing a modification example of an analysis section of the analysis apparatus according to the embodiment of the present invention.

### DESCRIPTION OF THE PREFERRED EMBODIMENTS

Hereinafter, an analysis apparatus and an analysis method according to an embodiment of the present invention will be described in detail based on the preferred embodiments shown in the accompanying drawings.

It should be noted that the drawings shown below are examples for describing the present invention, and the present invention is not limited to the drawings shown below.

It should be noted that, hereinafter, “to” indicating a numerical range includes the numerical values described on both sides thereof. For example, a case in which ε is a numerical value εₐ to a numerical value ε_{b} means a range of ε is a range including the numerical value Ea and the numerical value ε_{b}, and εₐ≤ε≤ε_{b} in a mathematical symbol.

Unless otherwise specified, angles, such as “angle represented by a specific numerical value”, “parallel”, “perpendicular”, and “orthogonal”, include an error range generally allowed in the corresponding technical field.

Also, the “same” includes an error range generally allowed in the corresponding technical field. In addition, the “entire surface” includes an error range generally allowed in the corresponding technical field.

[First Example of Analysis Apparatus]

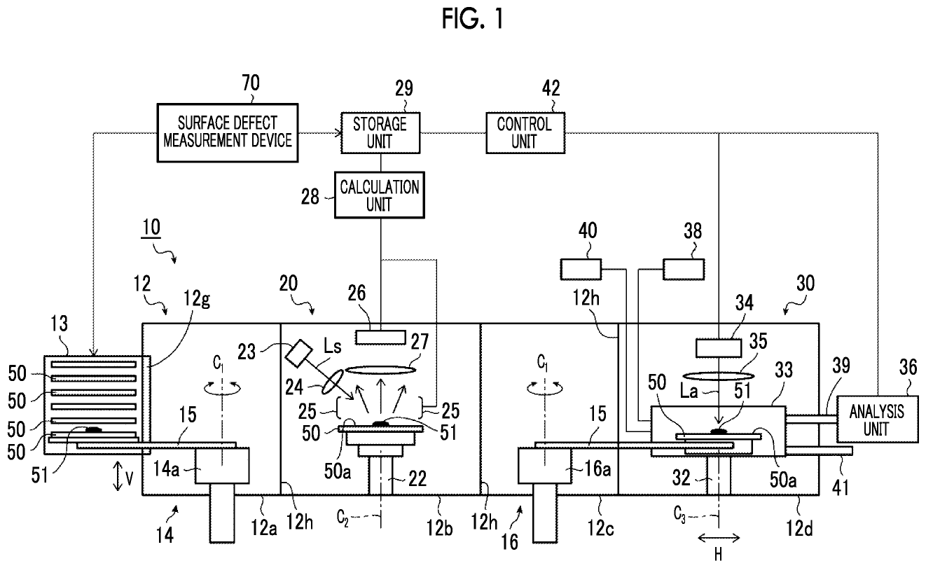

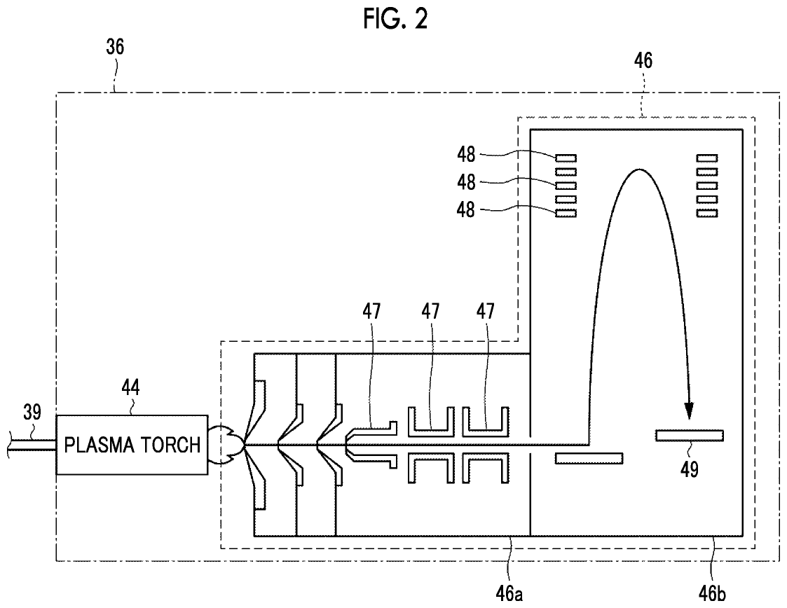

FIG. 1 is a schematic view showing a first example of the analysis apparatus according to the embodiment of the present invention, and FIG. 2 is a schematic view showing an example of an analysis unit of the first example of the analysis apparatus according to the embodiment of the present invention.

An analysis apparatus 10 shown in FIG. 1 includes a surface defect measurement unit 20 and an analysis section 30 which will be described in detail below. The analysis apparatus 10 performs the measurement of the presence or absence of a defect on a surface 50a of a semiconductor substrate 50 and the analysis of the defect on the surface 50a of the semiconductor substrate 50 with the semiconductor substrate 50 as a measurement target.

The analysis apparatus 10 includes a first transport chamber 12a, a measurement chamber 12b, a second transport chamber 12c, and an analysis chamber 12d, and the first transport chamber 12a, the measurement chamber 12b, the second transport chamber 12c, and the analysis chamber 12d are disposed consecutively in this order. The first transport chamber 12a, the measurement chamber 12b, the second transport chamber 12c, and the analysis chamber 12d are partitioned by walls 12h, but a door (not shown) or the like may be provided such that the semiconductor substrate 50 that is the measurement target can be moved, and the door may be opened in a case in which the semiconductor substrate 50 is passed through the door.

In the analysis apparatus 10, the semiconductor substrate 50 is transported to the first transport chamber 12a from the outside of the analysis apparatus 10 and is transported from the first transport chamber 12a to the measurement chamber 12b, and a surface defect of the semiconductor substrate 50 is measured in the measurement chamber 12b. Next, the semiconductor substrate 50 of which the surface defect is measured is transported from the measurement chamber 12b to the second transport chamber 12c and is further transported to the analysis chamber 12d, and the analysis section 30 analyzes the surface defect of the semiconductor substrate 50 based on a measurement result of the presence or absence of the defect on the surface 50a of the semiconductor substrate 50 by the surface defect measurement unit 20.

In the analysis apparatus 10, in order to prevent the semiconductor substrate 50 from being exposed to the outside air, the insides of the first transport chamber 12a, the measurement chamber 12b, the second transport chamber 12c, and the analysis chamber 12d can have a specific atmosphere. For example, a vacuum pump may be provided to exhaust the gas inside the first transport chamber 12a, the measurement chamber 12b, the second transport chamber 12c, and the analysis chamber 12d to obtain a reduced pressure atmosphere. In addition, an inert gas, such as nitrogen gas, may be supplied to the insides of the first transport chamber 12a, the measurement chamber 12b, the second transport chamber 12c, and the analysis chamber 12d to obtain an inert gas atmosphere inside.

The first transport chamber 12a transports the semiconductor substrate 50 transported from the outside of the analysis apparatus 10 to the measurement chamber 12b, as described above. An introduction portion 12g is provided on a side surface of the first transport chamber 12a. An accommodation container 13 is installed in the introduction portion 12g. A sealing member (not shown) is provided in the introduction portion 12g in order to maintain airtightness with the accommodation container 13.

In the accommodation container 13, for example, a plurality of semiconductor substrates 50 are disposed in a shelf shape and accommodated therein. For example, the semiconductor substrate 50 is a disk-shaped substrate.

For example, the accommodation container 13 is a front opening unified pod (FOUP). By using the accommodation container 13, the semiconductor substrate 50 can be transported to the analysis apparatus 10 in a sealed state without being exposed to the outside air. As a result, contamination of the semiconductor substrate 50 can be suppressed.

A transport device 14 is provided inside the first transport chamber 12a. The transport device 14 transports the semiconductor substrate 50 in the accommodation container 13 from the first transport chamber 12a to the adjacent measurement chamber 12b.

The transport device 14 is not particularly limited as long as the semiconductor substrate 50 can be taken out from the accommodation container 13 and transported to a stage 22 of the measurement chamber 12b.

The transport device 14 shown in FIG. 1 has a transport arm 15 that sandwiches the outside of the semiconductor substrate 50 and a driving unit (not shown) that drives the transport arm 15. The transport arm 15 is attached to an attachment portion 14a and is rotatable about a rotation axis C₁. It should be noted that the configuration of the transport arm 15 is not particularly limited to the configuration that sandwiches the outside of the semiconductor substrate 50 as long as the transport arm 15 can hold and transport the semiconductor substrate 50, and can be used appropriately for transport of a semiconductor wafer between processes.

In the transport device 14, the attachment portion 14a can be moved in a height direction V, and the transport arm 15 can be moved in the height direction V, which is a direction parallel to the rotation axis C₁. By moving the attachment portion 14a in the height direction V, a position of the transport arm 15 in the height direction V can be changed.

(Surface Defect Measurement Unit)

The surface defect of the semiconductor substrate 50 is measured in the measurement chamber 12b as described above. The surface defect measurement unit 20 is provided inside the measurement chamber 12b.

The surface defect measurement unit 20 measures the presence or absence of the defect on the surface 50a of the semiconductor substrate 50, and obtains positional information on the surface 50a of the semiconductor substrate 50 for the defect on the surface 50a of the semiconductor substrate 50.

The surface defect measurement unit 20 includes the stage 22 on which the semiconductor substrate 50 is placed, an incidence unit 23 that allows incidence rays Ls to be incident on the surface 50a of the semiconductor substrate 50, and a condenser lens 24 that condenses the incidence rays Ls on the surface 50a of the semiconductor substrate 50.

The stage 22 on which the semiconductor substrate 50 is placed is rotatable about a rotation axis C₂, can change a position of the semiconductor substrate 50 in the height direction V, and can change a position in a direction H orthogonal to the height direction V.

The stage 22 can change an irradiation position of the incidence rays Ls on the surface 50a of the semiconductor substrate 50. As a result, a specific region of the surface 50a of the semiconductor substrate 50 or the entire surface thereof can be sequentially irradiated with the incidence rays Ls to detect the defect, such as the foreign substance, on the surface 50a of the semiconductor substrate 50.

A wavelength of the incidence ray Ls emitted by the incidence unit 23 is not particularly limited. The incidence ray Ls is, for example, ultraviolet light, but may be visible light or other light. Here, the ultraviolet light is light in a wavelength range of less than 400 nm, and the visible light is light in a wavelength range of 400 to 800 nm.

An incidence angle of the incidence ray Ls is 0° in all directions horizontal to the surface 50a of the semiconductor substrate 50 and 90° in a direction perpendicular to the surface 50a of the semiconductor substrate 50. In this case, in a case in which the incidence angle of the incidence ray Ls is defined from 0° at minimum to 90° at maximum, the incidence angle of the incidence ray Ls is equal to or more than 0° and equal to or less than 90° or less, and preferably more than 0° and less than 90°.

The surface defect measurement unit 20 includes a light receiving unit that receives radiated rays radiated by the reflection or scattering of the incidence rays Ls on the surface 50a of the semiconductor substrate 50. The surface defect measurement unit 20 shown in FIG. 1 includes, for example, two light receiving units 25 and 26. In a case in which any of the light receiving units 25 and 26 receives the radiated rays, it is assumed that there is the defect on the surface 50a of the semiconductor substrate 50, and in a case in which the radiated rays are not generated, it is assumed that there is no defect on the surface 50a of the semiconductor substrate 50. In this way, the presence or absence of the defect on the surface 50a of the semiconductor substrate 50 is measured.

The light receiving unit 25 is disposed around the semiconductor substrate 50. The light receiving unit 26 is disposed above the surface 50a of the semiconductor substrate 50. A condenser lens 27 is provided between the surface 50a of the semiconductor substrate 50 and the light receiving unit 26. The condenser lens 27 condenses the radiated rays generated by the incidence rays Ls on the light receiving unit 26. The condenser lens 27 can efficiently condense the radiated rays to the light receiving unit 26. It should be noted that the number of light receiving units is not particularly limited to two. The surface defect measurement unit 20 may include any one of the light receiving unit 25 or the light receiving unit 26, or may have three or more light receiving units.

The light receiving unit 25 receives the radiated rays on a low angle side. The light reception on the low angle side means that the light is received in a range being equal to or more than 0° and equal to or less than 80° at the above-described incidence angle.

The light receiving unit 26 receives the radiated rays on a high angle side. The light reception on the high angle side means that the light is received in a range being more than 80° and equal to or less than 90° at the above-described incidence angle.

The light receiving unit 25 and the light receiving unit 26 are composed of, for example, an optical sensor, such as a photomultiplier tube.

In addition, both the light receiving unit 25 and the light receiving unit 26 can receive non-polarized light or polarized light.

The surface defect measurement unit 20 includes a calculation unit 28 and a storage unit 29.

The calculation unit 28 calculates the positional information of the detected defect and a size of the defect based on the information of the radiated rays received by the light receiving units 25 and 26. The positional information of the defect is information on position coordinates of the defect on the surface 50a of the semiconductor substrate 50. The position coordinates are set, for example, by setting a reference position common to the plurality of semiconductor substrates 50 in advance and setting the reference position as an origin.

The light receiving units 25 and 26 receive the radiated rays radiated by the reflection or scattering of the incidence rays Ls emitted by the incidence unit 23 due to the defect of the surface 50a of the semiconductor substrate 50. In the light receiving units 25 and 26, the radiated ray is detected as a bright spot. In the calculation unit 28, the light receiving units 25 and 26 calculate the size of the defect that causes the bright spot, that is, a detection size, based on a size of a standard particle from the size of the bright spot including the information of the radiated rays due to the defect. The calculation of the detection size based on the size of the standard particle is performed by a calculation device provided in a commercially available surface examination device or by a known calculation method. The calculation unit 28 acquires the positional information of the irradiation position of the incidence rays Ls from a control unit 42, and for example, the light receiving units 25 and 26 obtains the positional information of the defect on the surface 50a of the semiconductor substrate 50 and the information on the size of the defect based on the information of the radiated rays due to the defect. The positional information of the defect on the surface 50a of the semiconductor substrate 50 and the information on the size of the defect, which are obtained, are stored in the storage unit 29.

The storage unit 29 is not particularly limited as long as the positional information and the information on the size of the defect, such as the foreign substance, on the surface 50a of the semiconductor substrate 50 can be stored. For example, various storage media, such as a volatile memory, a non-volatile memory, a hard disk, and a solid state drive (SSD), can be used.

Here, in the surface defect measurement unit 20, the control unit 42 controls the stage 22 and the incidence unit 23. In addition, the calculation unit 28 is also controlled by the control unit 42.

The control unit 42 acquires the positional information of the incidence rays Ls emitted by the incidence unit 23 on the surface 50a of the semiconductor substrate 50. The control unit 42 drives the stage 22 and changes the irradiation position on the surface 50a of the semiconductor substrate 50 in order to irradiate a region on the surface 50a of the semiconductor substrate 50, which is not irradiated with the incidence rays Ls, with the incidence rays Ls.

The surface defect measurement unit 20 irradiates the entire region of the surface 50a of the semiconductor substrate 50 with the incidence rays Ls, and obtains the positional information of the defect on the surface 50a of the semiconductor substrate 50 and the information on the size of the defect at each irradiation position, for example, based on the information of the radiated rays received by the two light receiving units 25 and 26. As a result, it is possible to obtain the positional information of the defect on the entire surface of the surface 50a of the semiconductor substrate 50 and the information on the size of the defect. That is, two-dimensional defect positional information on the surface 50a of the semiconductor substrate 50 and the information on the size of the defect can be obtained.

At the time of the measurement by the surface defect measurement unit 20, the atmosphere of the measurement chamber 12b is not particularly limited, and may be the reduced pressure atmosphere or the nitrogen gas atmosphere as described above.

It should be noted that, as the surface defect measurement unit 20, for example, a surface examination device (SurfScan SP5; manufactured by KLA Corporation) can be used.

A transport device 16 is provided inside the second transport chamber 12c. The transport device 16 transports the semiconductor substrate 50 of which the surface defect is measured by the surface defect measurement unit 20 in the measurement chamber 12b from the measurement chamber 12b to the analysis chamber 12d.

As the transport device 16, the transport device having the same configuration as the transport device 14 can be used. The transport device 16 has the transport arm 15 that sandwiches the outside of the semiconductor substrate 50 and the driving unit (not shown) that drives the transport arm 15. The transport arm 15 is attached to an attachment portion 16a and is rotatable about the rotation axis C₁.

In the transport device 16, the attachment portion 16a can be moved in a height direction V, and can be moved in the height direction V, which is the direction parallel to the rotation axis C₁. The position of the transport arm 15 can be changed in the height direction V by moving the attachment portion 16a to which the transport arm 15 is attached in the height direction V.

(Analysis Section)

The analysis chamber 12d is provided with the analysis section 30 inside. The analysis section 30 performs analysis using a laser ablation-inductively coupled plasma mass spectrometer (LA-ICP-MS).

An inductively coupled plasma mass spectrometer (ICP-MS) performs the mass spectrometry by ionizing an element in a liquid sample using a plasma of an argon gas at about 10000° C. generated by the inductive coupling. The LA-ICP-MS performs quantitative analysis of elements contained in an analysis sample obtained by the irradiation by irradiating a defect 51 on the surface 50a of the semiconductor substrate 50 with the laser light in a laser ablation portion (LA portion), and introducing the analysis sample into an inductively coupled plasma mass spectrometry unit (ICP-MS unit) using the carrier gas.

The analysis section 30 includes a stage 32 on which the semiconductor substrate 50 is placed and a container portion 33 that accommodates the semiconductor substrate 50 placed on the stage 32.

The analysis unit 36 is connected to the container portion 33 through a pipe 39. The semiconductor substrate 50 is analyzed in a state in which the entire semiconductor substrate 50 is accommodated in the container portion 33. The stage 32 on which the semiconductor substrate 50 is placed is rotatable about a rotation axis C₃, can change the position of the semiconductor substrate 50 in the height direction V, and can change the position in the direction H orthogonal to the height direction V.

The stage 32 is controlled by the control unit 42. The control unit 42 drives the stage 32 and changes the irradiation position on the surface 50a of the semiconductor substrate 50 in order to irradiate the defect 51 on the surface 50a of the semiconductor substrate 50 with laser light La.

The analysis section 30 has a light source unit 34 that irradiates the defect 51 on the surface 50a of the semiconductor substrate 50 measured by the surface defect measurement unit 20 with the laser light La. A condenser lens 35 that condenses the laser light La on the defect 51 on the surface 50a of the semiconductor substrate 50 is provided between the light source unit 34 and the surface 50a of the semiconductor substrate 50.

The light source unit 34 and the condenser lens 35 are provided outside the container portion 33. The container portion 33 is provided with a window portion (not shown) through which the laser light La can be transmitted such that the laser light La is transmitted to the inside.

A femtosecond laser, a nanosecond laser, a picosecond laser, an atto second laser, or the like is used as the light source unit 34. For example, a Ti:Sapphire laser can be used as the femtosecond laser.

The analysis section 30 includes a carrier gas supply unit 38 that supplies the carrier gas to the inside of the container portion 33.

The carrier gas supply unit 38 includes a gas supply source (not shown), such as a cylinder in which the carrier gas is stored, a regulator (pressure regulator) connected to the gas supply source, and an adjusting valve (not shown) that controls a supply amount of the carrier gas. For example, the regulator and the adjusting valve are connected by a tube, and the adjusting valve and the container portion 33 are connected by a pipe. For example, a helium gas or an argon gas is used as the carrier gas.

In addition, the analysis section 30 includes a cleaning gas supply unit 40 that supplies a cleaning gas to the inside of the container portion 33. The cleaning gas supply unit 40 includes a gas supply source (not shown), such as a cylinder in which the cleaning gas is stored, a regulator (pressure regulator) connected to the gas supply source, and an adjusting valve (not shown) that controls a supply amount of the cleaning gas. For example, the regulator and the adjusting valve are connected by a tube, and the adjusting valve and the container portion 33 are connected by a pipe. For example, a helium gas or an argon gas is used as the cleaning gas.

In addition, the container portion 33 is provided with an outflow unit 41 that allows the cleaning gas to flow out from the inside of the container portion 33 to the outside. The outflow unit 41 is composed of a pipe and a valve, for example. By opening the valve, the cleaning gas can flow out from the inside of the container portion 33 to the outside.

The container portion 33 may be provided with a heater (not shown) in order to perform the flushing treatment. By heating the inside of the container portion 33 with the heater in a state in which the cleaning gas is supplied to the inside of the container portion 33, for example, the foreign substance such as ablated attachment, or adsorbed gas in the container portion 33 is removed. As a result, the cleanliness in the container portion 33 can be made higher, and the contamination of the semiconductor substrate 50 can be suppressed. It should be noted that, as the heater, for example, an infrared lamp or a xenon flash lamp is used.

Also, the carrier gas can also be used for the flushing treatment in addition to the cleaning gas.

<Analysis Unit>

The analysis unit 36 uses the above-described ICP-MS, and performs the inductively coupled plasma mass spectrometry by irradiating the defect 51 on the surface 50a of the semiconductor substrate 50 with the laser light La, and collecting the analysis sample obtained by the irradiation using the carrier gas. It should be noted that ICP is an abbreviation for inductively coupled plasma. In the analysis unit 36, the atomic species and the concentration of the detected atomic species are measured by ionizing the measurement target by the high-temperature plasma maintained by the high-frequency electromagnetic induction, and detecting the ions using the mass spectrometry device.

For example, as shown in FIG. 2, the analysis unit 36 includes a plasma torch 44 that generates the plasma that ionizes the analysis sample introduced from the pipe 39 together with the carrier gas, and a mass spectrometry unit 46 having an ion introduction portion located in the vicinity of a distal end part of the plasma torch 44.

The plasma torch 44 has, for example, a triple tube structure, and the carrier gas is introduced from the pipe 39. In addition, a plasma gas for plasma formation is introduced into the plasma torch 44. As the plasma gas, for example, the argon gas is used.

The plasma torch 44 is provided with a high-frequency coil (not shown) connected to a high-frequency power source (not shown), and the plasma is formed inside the plasma torch 44 by applying, for example, a high-frequency current of about 27.12 MHz or 40.68 MHz and 1 to 2 KW to this high-frequency coil.

In the mass spectrometry unit 46, the ions generated in the plasma torch 44 are introduced into an ion lens portion 46a and a mass spectrometer unit 46b through the ion introduction portion. The pressures inside the ion lens portion 46a and the mass spectrometer unit 46b are reduced by a vacuum pump (not shown) such that the ion lens portion 46a on the plasma torch 44 side has a low vacuum and the mass spectrometer unit 46b has a high vacuum.

The ion lens portion 46a is provided with a plurality of (for example, three) ion lenses 47. The ion lens 47 separates the ions to the mass spectrometer unit 46b.

In the ion lens portion 46a of the mass spectrometry unit 46, light of the above-described plasma and the ions are separated by the ion lens 47 and only the ions pass through.

The mass spectrometer unit 46b separates the ions for each mass-to-charge ratio of the ions and detects the separated ions by a detector 49. The mass spectrometer unit 46b includes a reflectron 48 and the detector 49 that detects the ions passing through the ion lens portion 46a. The reflectron 48 is also called an ion mirror, and is a device that reverses a flight direction of the charged particles by using an electrostatic field. By using the reflectron 48, the charged particles having the same mass-charge ratio and different kinetic energies can be converged on a time axis and reach the detector 49 in substantially the same time. The reflectron 48 compensates for an error and can improve a mass resolution. As the reflectron 48, a known reflectron used in a time-of-flight mass spectrometer (TOF-MS) can be used.

The detector 49 is not particularly limited as long as the ions can be detected and the elements can be specified, and a known detector used in the time-of-flight mass spectrometer (TOF-MS) can be used.

With the analysis unit 36, for example, a signal (not shown) of the detection element ions can be displayed as a chart for each time (not shown). The concentration of the detection element corresponds to the signal intensity.

As shown in FIG. 1, the analysis apparatus 10 includes the control unit 42, and the control unit 42 drives the stage 32 of the analysis section 30 or changes the irradiation position of the laser light La to irradiates the defect 51 on the surface 50a of the semiconductor substrate 50 with the laser light La, based on the positional information and the information on the size of the defect, such as the foreign substance, on the surface 50a of the semiconductor substrate 50 detected as described above, which are stored in the storage unit 29 of the surface defect measurement unit 20. As a result, the defect 51 on the surface 50a of the semiconductor substrate 50 is analyzed.

In addition, the analysis apparatus 10 can suppress the contamination of the surface 50a of the semiconductor substrate 50 by the configuration in which the inductively coupled plasma mass spectrometry can be performed by the analysis section 30 in a state in which the entire semiconductor substrate 50 is accommodated in the container portion 33.

In the analysis apparatus 10, the carrier gas and the cleaning gas are supplied by separate systems, but the present invention is not limited to this. Since the supply timings of the carrier gas and the cleaning gas are different from each other, the carrier gas and the cleaning gas may share one disposition to be supplied to the container portion 33. For example, a configuration may be adopted in which only the carrier gas supply unit 38 is provided without providing the cleaning gas supply unit 40.

In addition, it is preferable that the carrier gas has a moisture content being equal to or more than 0.00001 ppm by volume and equal to or less than 0.1 ppm by volume.

In a case in which the moisture content of the carrier gas is equal to or more than 0.00001 ppm by volume and equal to or less than 0.1 ppm by volume, the contamination of the surface 50a of the semiconductor substrate 50 being analyzed in the container portion 33 can be reduced. For example, in a case in which the moisture content of the carrier gas is large, impurities are eluted in a small amount of moisture adhering to a pipe surface of the carrier gas or an inner surface of the container portion 33, and the impurities are reattached to the semiconductor substrate 50 to cause an increase in the number of defects. However, the above-described cases are suppressed in a case in which the moisture content of the carrier gas is within the above-described range.

In addition, in a case in which the moisture content is small, the surface 50a of the semiconductor substrate 50 is likely to be charged in a case in which the carrier gas passes in the vicinity of the semiconductor substrate 50. As a result, it is easy to invite the charged particles floating in the container portion 33 to the surface 50a of the semiconductor substrate 50 or to attract the particles floating in the vicinity thereof during transport in the transport system to the surface 50a of the semiconductor substrate 50. In addition, the reattachment of a product resulting from the laser ablation is likely to occur, but this case is suppressed in a case in which the moisture content of the carrier gas is within the above-described range.

The moisture content of the carrier gas can be measured by using an atmospheric pressure Ionization mass spectrometer (API-MS). More specifically, the moisture content of the carrier gas can be measured by using, for example, a device manufactured by NIPPON API CO., LTD.

The method of adjusting the moisture content is not particularly limited, and is realized by performing a gas purification step of adjusting the moisture content by removing water (steam) contained in a raw material gas. In particular, the moisture content of the carrier gas can be adjusted by adjusting the number of purifications or a filter.

It should be noted that it is desirable that a flow rate of the carrier gas is 1.69×10⁻³ to 1.69 Pa·m³/sec (1 to 1000 standard cubic centimeter per minute (sccm)).

[First Example of Analysis Method]

The analysis method includes a step of measuring the presence or absence of the defect on the surface of the semiconductor substrate, and obtaining the positional information on the surface of the semiconductor substrate for the defect on the surface of the semiconductor substrate, and a step of performing the inductively coupled plasma mass spectrometry by irradiating the defect on the surface of the semiconductor substrate with the laser light based on the positional information of the defect on the surface of the semiconductor substrate, and collecting the analysis sample obtained by the irradiation using the carrier gas. The analysis method will be described in detail.

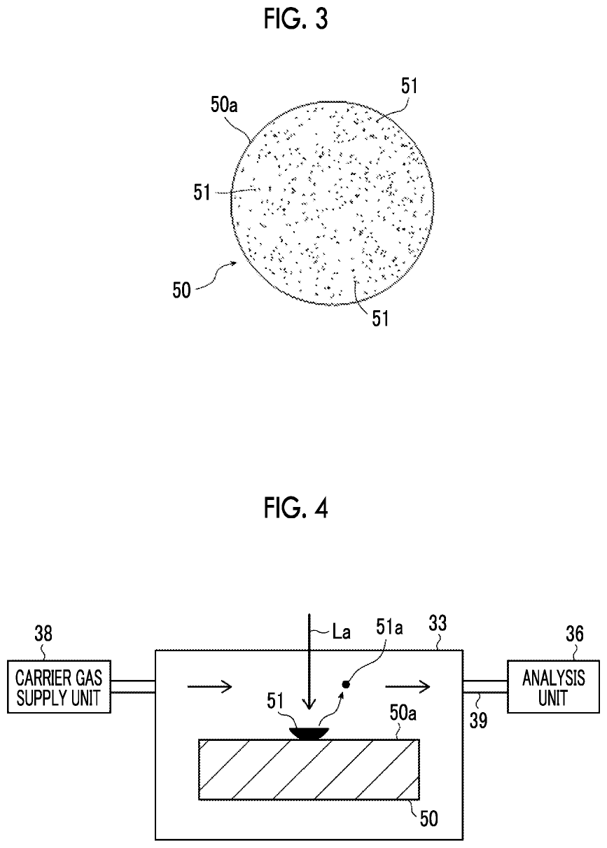

FIG. 3 is a schematic view showing a first example of the analysis method according to the embodiment of the present invention, and FIG. 4 is a schematic cross-sectional view showing the first example of the analysis method according to the embodiment of the present invention.

It should be noted that, in FIG. 3 and FIG. 4, the same components as those of the analysis apparatus 10 shown in FIG. 1 are designated by the same reference numerals, and the detailed description thereof will be omitted.

In the analysis method, for example, an accommodation container 13 (see FIG. 1) in which the plurality of semiconductor substrates 50 are accommodated is connected to the introduction portion 12g on the side surface of a first transport chamber 12a of the analysis apparatus 10 shown in FIG. 1. A lid of the accommodation container 13 is opened such that the semiconductor substrate 50 can be taken out from the accommodation container 13.

Next, by using the transport device 14 of the first transport chamber 12a, the semiconductor substrate 50 is taken out from the accommodation container 13, and the semiconductor substrate 50 is transported to the stage 22 of the measurement chamber 12b. In the step of transporting the semiconductor substrate 50 from the inside of the accommodation container 13 to the stage 22 of the measurement chamber 12b, the contamination of the semiconductor substrate 50 is suppressed even in a case in which the semiconductor substrate 50 is transported from the outside of the analysis apparatus 10. The surface defect of the semiconductor substrate 50 can be measured by the surface defect measurement unit 20 in a state in which the contamination of the semiconductor substrate 50 is suppressed.

Then, the surface defect of the semiconductor substrate 50 is measured by the surface defect measurement unit 20 in the measurement chamber 12b. As a result, the positional information and the size of the defect, such as the foreign substance, on the surface 50a of the semiconductor substrate 50 are detected. For example, as shown in FIG. 3, the defect 51 can be shown on the surface 50a of the semiconductor substrate 50. Showing the defect 51 on the surface 50a of the semiconductor substrate 50 is referred to as mapping. The positional information and the information on the size of the defect 51 on the surface 50a of the semiconductor substrate 50 are stored in the storage unit 29. The positional information and the information on the size of the defect 51 on the surface 50a of the semiconductor substrate 50 is referred to as mapping information.

Next, the semiconductor substrate 50 of which the surface defect is measured is transported from the measurement chamber 12b to the analysis chamber 12d by the transport device 16 of the second transport chamber 12c shown in FIG. 1.

Then, in the analysis chamber 12d, the analysis section 30 performs the analysis based on the positional information and the information on the size of the defect 51 on the surface 50a of the semiconductor substrate 50, that is, the mapping information. As shown in FIG. 4, the analysis is performed in a state in which the entire semiconductor substrate 50 is accommodated in the container portion 33 and in a state in which the carrier gas (not shown) is supplied from the carrier gas supply unit 38 to the inside of the container portion 33. In the analysis, the position of the defect 51 is specified based on the mapping information, and for example, the semiconductor substrate 50 is moved by using the stage 32 such that the defect 51 is at the irradiation position of the laser light La.

Then, as shown in FIG. 4, the defect 51 on the surface 50a of the semiconductor substrate 50 is irradiated with the laser light La. An analysis sample 51a obtained by irradiating the defect 51 with the laser light La is moved to the analysis unit 36 through the pipe 39 by the carrier gas (not shown). In the analysis unit 36, the analysis sample 51a derived from the defect 51, which is moved by the carrier gas, is subjected to the inductively coupled plasma mass spectrometry to specify the element of the defect 51.

It is preferable that the analysis method includes a step of cleaning the inside of the container portion 33 using the cleaning gas before the step of performing the inductively coupled plasma mass spectrometry. Specifically, the step of cleaning is a step of supplying the cleaning gas to the inside of the container portion 33, and heating the inside of the container portion 33 by using a heater to perform the flushing treatment, before transporting the semiconductor substrate 50 to the inside of the container portion 33. In the step of cleaning, for example, the foreign substance such as the ablated attachment, or the adsorbed gas in the container portion 33 is removed.

In addition, in the analysis apparatus 10, the positional information of the defect 51 on the surface 50a of the semiconductor substrate 50, which is obtained by measuring the defect 51 on the surface 50a of the semiconductor substrate 50 by another device different from the analysis apparatus 10, for example, a surface defect measurement device 70 (see FIG. 1), can be used. The positional information of the defect 51 on the surface 50a of the semiconductor substrate 50 is, for example, the mapping information as shown in FIG. 3. In this case, the mapping information acquired by the surface defect measurement device 70 is supplied to the storage unit 29. Further, in the surface defect measurement device 70, the semiconductor substrate 50 of which the defect 51 on the surface 50a is measured is accommodated in, for example, the accommodation container 13 and transported to the analysis apparatus 10. The semiconductor substrate 50 is transported to the analysis chamber 12d through the first transport chamber 12a, the measurement chamber 12b, and the second transport chamber 12c.

Then, the control unit 42 reads out the mapping information from the storage unit 29 and specifies the position of the defect 51 on the surface 50a of the semiconductor substrate 50 based on the mapping information. Next, the semiconductor substrate 50 is moved by using the stage 32 such that the defect 51 is at the irradiation position of the laser light La. Then, the defect 51 on the surface 50a of the semiconductor substrate 50 is irradiated with the laser light La. The analysis sample 51a obtained by irradiating the defect 51 with the laser light La is moved to the analysis unit 36 by the carrier gas. In the analysis unit 36, the analysis sample 51a derived from the defect 51, which is moved by the carrier gas, is subjected to the inductively coupled plasma mass spectrometry to specify the element of the defect 51.

As described above, in a case in which the defect 51 is analyzed by using the mapping information as shown in FIG. 3 measured by the surface defect measurement device 70 (see FIG. 1), the semiconductor substrate 50 and the measurement of the surface defect of the surface defect measurement unit 20 are not required. It should be noted that, of course, the analysis apparatus 10 may not be provided with the surface defect measurement device 70 shown in FIG. 1.

It should be noted that the positional information of the defect 51 on the surface 50a of the semiconductor substrate 50 supplied to the storage unit 29 is not particularly limited to the positional information measured by the surface defect measurement device 70 (see FIG. 1). The surface defect measurement device 70 may include, for example, a storage unit (not shown) that stores the positional information. Also, the surface defect measurement device 70 may have the same configuration as the surface defect measurement unit 20 (see FIG. 1). Therefore, the surface defect measurement device 70 includes, for example, the incidence unit 23 that allows the incidence rays Ls to be incident on the surface 50a of the semiconductor substrate 50, and the light receiving unit 26 that receives the radiated rays radiated by the reflection or scattering of the incidence rays Ls due to the defect 51 of the surface 50a of the semiconductor substrate 50.

[Second Example of Analysis Apparatus]

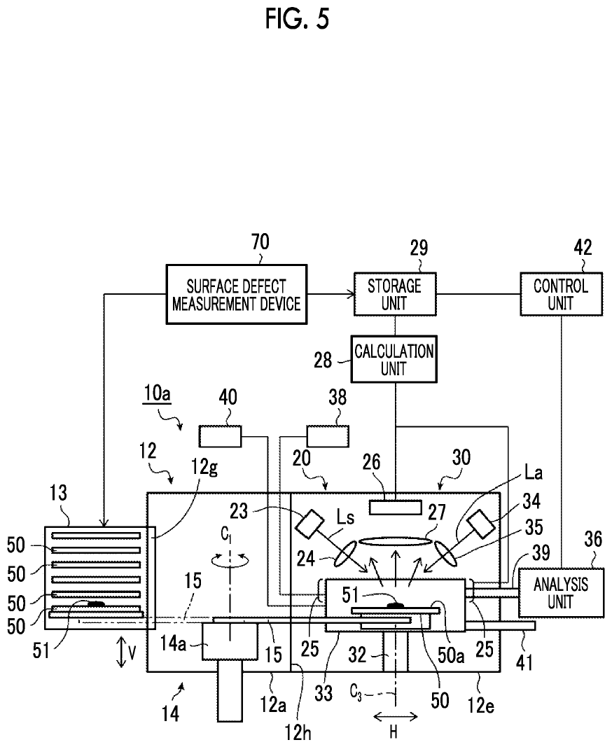

FIG. 5 is a schematic view showing a second example of the analysis apparatus according to the embodiment of the present invention. It should be noted that, in FIG. 5, the same components as those of the analysis apparatus 10 shown in FIG. 1 are designated by the same reference numerals, and the detailed description thereof will be omitted.

An analysis apparatus 10a shown in FIG. 5 is different from the analysis apparatus 10 shown in FIG. 1 in that the second transport chamber 12c and the transport device 16 are not provided, and in that the surface defect measurement unit 20 and the analysis section 30 are provided inside one treatment chamber 12e, and other configurations are the same as those of the analysis apparatus 10 shown in FIG. 1.

In the analysis apparatus 10a, the measurement of the surface defect and the analysis are performed in a state in which the entire semiconductor substrate 50 is accommodated in the container portion 33.

In the analysis section 30, the light source unit 34 is disposed such that an optical axis of the laser light La is inclined with respect to the surface 50a of the semiconductor substrate 50.

In the analysis apparatus 10a, by providing the surface defect measurement unit 20 and the analysis section 30 in one treatment chamber 12e, the size of the apparatus can be reduced as compared with the analysis apparatus 10 shown in FIG. 1.

In addition, with the configuration in which measurement of the surface defect by the surface defect measurement unit 20 and the inductively coupled plasma mass spectrometry by the analysis section 30 can be performed in a state in which the entire semiconductor substrate 50 is accommodated in the container portion 33, the transport of the semiconductor substrate 50 is reduced, and the contamination of the surface 50a of the semiconductor substrate 50 can be further suppressed. As a result, the accuracy of the measurement of the defect on the surface 50a of the semiconductor substrate 50 can be made higher, and the contamination in the treatment chamber 12e of the analysis apparatus 10a can be further suppressed.

[Second Example of Analysis Method]

A second example of the analysis method is basically the same as the first example of the analysis method described above. The second example of the analysis method is different from the first example of the analysis method described above in that the measurement of the surface defect by the surface defect measurement unit 20 is performed in a state in which the entire semiconductor substrate 50 is accommodated in the container portion 33, and in that the semiconductor substrate 50 of which the surface defect is measured is not transported by the transport device 16 (see FIG. 1) from the measurement chamber 12b (see FIG. 1) to the analysis chamber 12d (see FIG. 1) after the measurement of the surface defect, and other configurations are the same as those of the first example of the analysis method.

In the second example of the analysis method, by performing measurement of the surface defect by the surface defect measurement unit 20 and the inductively coupled plasma mass spectrometry by the analysis section 30 in a state in which the entire semiconductor substrate 50 is accommodated in the container portion 33, the contamination of the surface 50a of the semiconductor substrate 50 can be further suppressed, and the contamination of the inside of the treatment chamber 12e of the analysis apparatus 10a can be further suppressed.

In addition, as described above, by performing the measurement of the surface defect by the surface defect measurement unit 20 and the inductively coupled plasma mass spectrometry by the analysis section 30 in a state in which the entire semiconductor substrate 50 is accommodated in the container portion 33, the transport of the semiconductor substrate 50 between the steps is not required, and the analysis time can be reduced as compared with the first example of the analysis method. Furthermore, as described above, the contamination of the surface 50a of the semiconductor substrate 50 can be further suppressed.

In addition, even in the analysis apparatus 10a, similarly to the analysis apparatus 10, the mapping information shown in FIG. 3, which is obtained by measuring the defect 51 on the surface 50a of the semiconductor substrate 50 by another device different from the analysis apparatus 10a, for example, a surface defect measurement device 70 (see FIG. 5), can be used. In this case, the mapping information acquired by the surface defect measurement device 70 is supplied to the storage unit 29. Further, in the surface defect measurement device 70, the semiconductor substrate 50 of which the defect 51 on the surface 50a is measured is accommodated in, for example, the accommodation container 13 and transported to the analysis apparatus 10a.

In the analysis apparatus 10a, based on the mapping information, the analysis sample 51a derived from the defect 51 is subjected to the inductively coupled plasma mass spectrometry in the analysis unit 36d by the analysis section 30 in the treatment chamber 12e as described above, and the element of the defect 51 is specified.

Even in this case, in a case in which the mapping information measured by the surface defect measurement device 70 (see FIG. 5) is used, the semiconductor substrate 50 and the measurement of the surface defect of the surface defect measurement unit 20 are not required. It should be noted that, of course, the analysis apparatus 10a may not be provided with the surface defect measurement device 70 shown in FIG. 5, similarly to the analysis apparatus 10. In addition, the positional information of the defect 51 on the surface 50a of the semiconductor substrate 50 supplied to the storage unit 29 is not particularly limited to the positional information measured by the surface defect measurement device 70 (see FIG. 5).

[Third Example of Analysis Apparatus]

As described above, in a case in which the mapping information measured by a device other than the analysis apparatus, for example, the surface defect measurement device 70 is used, the surface defect measurement unit is not always required in the analysis apparatus, and the analysis apparatus may be a configuration in which the surface defect measurement unit is not provided. In this case, the analysis apparatus has a configuration in which only the analysis section 30 is provided (see FIG. 1).

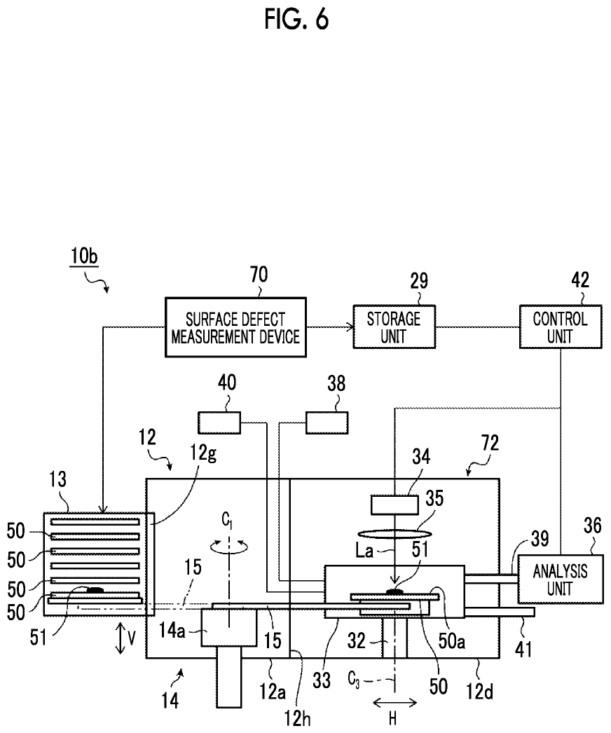

FIG. 6 is a schematic view showing a third example of the analysis apparatus according to the embodiment of the present invention. It should be noted that, in FIG. 6, the same components as those of the analysis apparatus 10 shown in FIG. 1 and the analysis apparatus 10a shown in FIG. 5 are designated by the same reference numerals, and the detailed description thereof will be omitted.

An analysis apparatus 10b shown in FIG. 6 is different from the analysis apparatus 10 shown in FIG. 1 in that the first transport chamber 12a, the transport device 14, the measurement chamber 12b, the surface defect measurement unit 20, the second transport chamber 12c, and the transport device 16 are not provided. In addition, the analysis apparatus 10b uses the analysis section 30 (see FIG. 1) as the mass spectrometry device 72, and includes the surface defect measurement device 70 and a mass spectrometry device 72. Since the mass spectrometry device 72 has the same configuration as the analysis section 30 (see FIG. 1), the detailed description of the mass spectrometry device 72 will be omitted.

In the analysis apparatus 10b, the surface defect measurement device 70 and the mass spectrometry device 72 are separate devices and are not integrated. In this case, the mapping information acquired by the surface defect measurement device 70 is supplied to the storage unit 29. Further, in the surface defect measurement device 70, the semiconductor substrate 50 of which the defect 51 on the surface 50a is measured is accommodated in, for example, the accommodation container 13 and transported to the mass spectrometry device 72. The semiconductor substrate 50 is transported to the analysis chamber 12d through the first transport chamber 12a.

Next, in the mass spectrometry device 72, the control unit 42 reads out the mapping information from the storage unit 29, and based on the mapping information, the analysis sample 51a derived from the defect 51 is subjected to the inductively coupled plasma mass spectrometry in the analysis unit 36d in the analysis chamber 12d as described above, and the element of the defect 51 is specified. In addition, as the positional information of the defect 51 on the surface 50a of the semiconductor substrate 50 supplied to the storage unit 29, the positional information other than the positional information measured by the surface defect measurement device 70 (see FIG. 6) can be used.

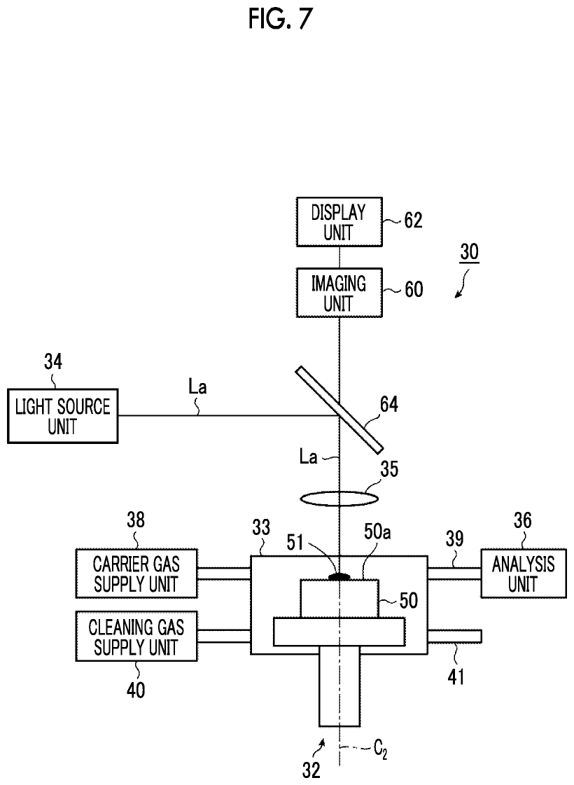

The analysis apparatus 10, the analysis section 30 of the analysis apparatus 10a, and the mass spectrometry device 72 of the analysis apparatus 10b are all not limited to the configuration of the analysis section 30. Here, FIG. 7 is a schematic view showing a modification example of the analysis section of the analysis apparatus according to the embodiment of the present invention. It should be noted that, in FIG. 7, the same components as those of the analysis apparatus 10 shown in FIG. 1 are designated by the same reference numerals, and the detailed description thereof will be omitted.

As shown in FIG. 7, in the analysis section 30, an imaging unit 60 that observes the surface 50a of the semiconductor substrate 50 and a display unit 62 that displays an image obtained by the imaging unit 60 may be provided.

The imaging unit 60 can observe the irradiation position of the laser light La on the surface 50a of the semiconductor substrate 50, that is, the position of the defect 51. Examples of the imaging unit 60 include a charge coupled device (CCD) sensor and a complementary metal oxide semiconductor (CMOS) sensor. Examples of the display unit 62 include a liquid crystal monitor and an organic electro luminescence (EL) monitor.

The light source unit 34 and the imaging unit 60 are disposed, for example, with their optical axes (not shown) orthogonal to each other. The imaging unit 60 is disposed to face the surface 50a of the semiconductor substrate 50.

A half mirror 64 is disposed at a position at which the optical axis of the light source unit 34 and the optical axis of the imaging unit 60 intersect. The laser light La emitted by the light source unit 34 is reflected by the half mirror 64, passes through the condenser lens 35, and is emitted to the surface 50a of the semiconductor substrate 50.

(Semiconductor Substrate)

The semiconductor substrate is not particularly limited, and various semiconductor substrates, such as a silicon (Si) substrate, a sapphire substrate, a SiC substrate, a GaP substrate, a GaAs substrate, an InP substrate, or a GaN substrate, can be used. As the semiconductor substrate, the silicon semiconductor substrate is widely used.

The present invention is basically configured as described above. Although the analysis apparatus and the analysis method according to the embodiment of the present invention have been described in detail above, the present invention is not limited to the above-described embodiment, and it is needless to say that various improvements or changes may be made without departing from the gist of the present invention.

### EXAMPLES

Hereinafter, the present invention will be described in more detail based on Examples. The materials, the usage amounts, the ratios, the processing contents, the treatment procedures, and the like shown in Examples can be appropriately changed without departing from the spirit of the present invention. Therefore, the scope of the present invention should not be construed as being limited by Examples.

Examples 1 to 29 and Comparative Examples 1 to 3 will be described below.

### Examples 1 to 20

In Examples, a dispersion liquid containing Fe nanoparticles having a size of 10 to 20 nm was prepared. The dispersion liquid was diluted and adjusted such that the number of particles was approximately 1 number/cm² on the silicon substrate having a diameter of 300 mm. The adjusted dispersion liquid was applied onto the silicon substrate having the diameter of 300 mm by using an electrostatic spray device.

The silicon substrate coated with the dispersion liquid was accommodated in the accommodation container that can accommodate the entire silicon substrate and transported to the surface defect measurement unit.

The surface examination device (SurfScan SP5; manufactured by KLA Corporation) was used as the surface defect measurement unit. In the surface examination device, by allowing the laser light to be incident on the surface of the silicon substrate and measuring the scattered light, the position and the size of the defect on the silicon substrate were measured, and the positional information of the defect and the information on the size of the defect were obtained and stored in the storage unit.

Next, the silicon substrate of which the surface defect was measured was transported to the analysis section. A laser ablation-inductively coupled plasma mass spectrometry (LA-ICP-MS) device was used as the analysis section. It should be noted that, in a case in which the silicon substrate was transported from the surface defect measurement unit to the analysis section, the silicon substrate was transported in a state of being isolated from the outside air. In a case in which the accommodation container described above was used, in transporting the silicon substrate, the silicon substrate was maintained in a state of being isolated from the outside air from beginning to end.

Based on the positional information of the defect and the information on the size of the defect, which were obtained, the element analysis of the defect by laser ablation was performed by using a laser ablation ICP mass spectrometry device, and it was confirmed whether or not Fe could be detected at a predetermined position subjected to the laser ablation.

The laser ablation was performed in a state in which the silicon substrate was accommodated in the container portion and in a state in which the carrier gas was supplied. The analysis sample obtained by the laser ablation was collected using the carrier gas and subjected to the inductively coupled plasma mass spectrometry. The femtosecond laser was used for the laser ablation.

Thereafter, the confirmation of the contamination status of the silicon substrate in the surface defect measurement unit, that is, whether or not the silicon substrate was contaminated during the analysis and whether or not the defect was ablated was performed. In addition, the moisture concentration in the carrier gas is shown in Table 1 and Table 2.

As the carrier gas, the argon gas was used. The flow rate of the carrier gas was 1.69×10⁻² Pa m³/sec (10 sccm).

It should be noted that, in Examples 1 to 14, the inside of the container portion was cleaned by performing the flushing treatment using the carrier gas before performing the element analysis of the defect by the laser ablation. In Examples 15 to 20, the inside of the container portion was not cleaned by the flushing treatment using the carrier gas.

### Examples 21 to 29

Examples 21 to 26 are different from Example 1 in that the silicon substrate was transported without using the accommodation container that accommodates the semiconductor substrate, and other configurations are the same as those of Example 1. In Examples 21 to 26, in a case in which the silicon substrate was transported from the surface defect measurement unit to the analysis section, the silicon substrate was transported in a state of being exposed to the outside air.

Examples 27 to 29 is different from Example 1 in that the silicon substrate was transported without using the accommodation container that accommodates the semiconductor substrate and in that the inside of the container portion was not cleaned using the carrier gas, and other configurations are the same as those of Example 1. In Examples 27 to 29, in a case of transporting the silicon substrate from the surface defect measurement unit to the analysis section, the silicon substrate was transported in a state of being exposed to the outside air.

A front opening unified pod (FOUP) was used as the accommodation container that accommodates the semiconductor substrate. In a case in which the accommodation container was used, “Presence” was described in the column of the accommodation container for the semiconductor substrate in Table 1 and Table 2. On the other hand, in a case in which the accommodation container was not used, “Absence” was described in the column of the accommodation container for the semiconductor substrate in Table 1 and Table 2.

### Comparative Examples 1 to 3

In Comparative Examples 1 to 3, the surface examination device (SurfScan SP5; manufactured by KLA Corporation) was used, by allowing the laser to be incident on the surface of the silicon substrate and measuring the scattered light, the position and the size of the defect on the silicon substrate were measured, and the positional information of the defect and the information on the size of the defect were obtained and stored in the storage unit.

Next, based on the positional information of the defect and the information on the size of the defect, which were obtained, an attempt was made to perform qualitative element analysis of the defect on the silicon substrate by using a defect review device (SEMVision G6 (manufactured by Applied Materials, Inc)). The qualitative element analysis of the defect on the silicon substrate of Comparative Examples 1 to 3 was performed by using a scanning electron microscope-energy dispersive X-ray spectroscopy (SEM-EDS).

In Comparative Examples 1 to 3, the SEM-EDS was used for the qualitative element analysis of the defect on the silicon substrate as described above. Since the SEM-EDS was performed under vacuum by an electron beam, the carrier gas was not used. For this reason, in Comparative Examples 1 to 3, “-” was described in the column of “Moisture content of carrier gas” in Table 2.

Since the container portion was not provided in Comparative Examples 1 to 3, “-” is described in the column of “Step of cleaning container portion” in Table 2.

TABLE 1

| | | Defect on surface of | | | Moisture | | Defect on surface of |
|---|---|---|---|---|---|---|---|
| | Accommodation | semiconductor | | Step of | content of | | semiconductor |
| | container of | substrate before | | cleaning | carrier gas | | substrate after |
| | semiconductor | analysis | Type of | container | (ppm by | Element | analysis |
| | substrate | (number/substrate) | carrier gas | portion | volume) | detection | (number/substrate) |
| Example 1 | Presence | 695 | Ar | Presence | 0.1 | Possible | 14 |
| Example 2 | Presence | 707 | Ar | Presence | 0.01 | Possible | 9 |
| Example 3 | Presence | 658 | Ar | Presence | 0.001 | Possible | 13 |
| Example 4 | Presence | 679 | He | Presence | 0.1 | Possible | 20 |
| Example 5 | Presence | 750 | He | Presence | 0.01 | Possible | 11 |
| Example 6 | Presence | 773 | He | Presence | 0.001 | Possible | 15 |
| Example 7 | Presence | 787 | Ar | Presence | 1000 | Possible | 151 |
| Example 8 | Presence | 549 | Ar | Presence | 100 | Possible | 109 |
| Example 9 | Presence | 659 | Ar | Presence | 10 | Possible | 94 |
| Example 10 | Presence | 788 | Ar | Presence | 0.000005 | Possible | 99 |
| Example 11 | Presence | 639 | He | Presence | 1000 | Possible | 168 |
| Example 12 | Presence | 731 | He | Presence | 100 | Possible | 138 |
| Example 13 | Presence | 745 | He | Presence | 10 | Possible | 108 |
| Example 14 | Presence | 744 | He | Presence | 0.000005 | Possible | 113 |
| Example 15 | Presence | 695 | Ar | Absence | 0.1 | Possible | 56 |
| Example 16 | Presence | 707 | Ar | Absence | 0.01 | Possible | 35 |

TABLE 2

| | | Defect on surface of | | | Moisture | | Defect on surface of |
|---|---|---|---|---|---|---|---|
| | Accommodation | semiconductor | | Step of | content of | | semiconductor |
| | container of | substrate before | | cleaning | carrier gas | | substrate after |
| | semiconductor | analysis | Type of | container | (ppm by | Element | analysis |
| | substrate | (number/substrate) | carrier gas | portion | volume) | detection | (number/substrate) |
| Example 17 | Presence | 658 | Ar | Absence | 0.001 | Possible | 77 |
| Example 18 | Presence | 679 | He | Absence | 0.1 | Possible | 46 |
| Example 19 | Presence | 750 | He | Absence | 0.01 | Possible | 27 |
| Example 20 | Presence | 773 | He | Absence | 0.001 | Possible | 44 |
| Example 21 | Absence | 2016 | Ar | Presence | 0.1 | Possible | 133 |
| Example 22 | Absence | 1870 | Ar | Presence | 0.01 | Possible | 95 |
| Example 23 | Absence | 1901 | Ar | Presence | 0.001 | Possible | 161 |
| Example 24 | Absence | 2108 | He | Presence | 0.1 | Possible | 155 |
| Example 25 | Absence | 2060 | He | Presence | 0.01 | Possible | 75 |
| Example 26 | Absence | 1790 | He | Presence | 0.001 | Possible | 172 |
| Example 27 | Absence | 2016 | Ar | Absence | 0.1 | Possible | 198 |
| Example 28 | Absence | 1870 | Ar | Absence | 0.01 | Possible | 167 |
| Example 29 | Absence | 1901 | Ar | Absence | 0.001 | Possible | 203 |
| Comparative | Presence | 790 | Ar | — | — | Impossible | 808 |
| Example 1 | | | | | | | |
| Comparative | Presence | 635 | Ar | — | — | Impossible | 655 |
| Example 2 | | | | | | | |
| Comparative | Presence | 689 | Ar | — | — | Impossible | 701 |
| Example 3 | | | | | | | |

As shown in Table 1 and Table 2, in Examples 1 to 29, the target Fe particles were ablated by the step of performing the analysis, and Fe was detected by the element analysis.

In Examples 1 to 29, since the number of defects on the silicon substrate decreased after the analysis, and the defect on the silicon substrate did not increase, it was confirmed that the ablation could be performed. It should be noted that it was considered that the reason why the number of defects on the silicon substrate after the analysis was not zero was that the contamination during the analysis could not be reduced to zero.

On the other hand, in Comparative Examples 1 to 3, the laser ablation ICP mass spectrometry device was not used, and the sensitivity of the element analysis of SEM-EDS was insufficient. Therefore, the qualitative element analysis of the defect could not be performed, and Fe could not be detected.

In addition, from Examples 1 to 29, it was also confirmed that the contamination of the surface of the silicon substrate during the analysis could be reduced by setting the concentration of impurities in the carrier gas to be equal to or more than 0.00001 ppm and equal to or less than 0.1 ppm. That is, by adjusting the moisture content of the carrier gas, the cleaning could be performed simultaneously with the analysis.

From the comparison between Examples 1 to 6 and Examples 15 to 20, it was confirmed that by providing the step of cleaning, the contamination of the silicon substrate during the analysis was further reduced.

From the comparison between Examples 1 to 20 and Examples 21 to 29, it was confirmed that in a case in which the accommodation container that accommodates the semiconductor substrate was used, the silicon substrate before the analysis was less likely to be contaminated.

### EXPLANATION OF REFERENCES

10, 10a, 10b: analysis apparatus
12a: first transport chamber
12b: measurement chamber
12c: second transport chamber
12d: analysis chamber
12e: treatment chamber
12g: introduction portion
12h: wall
13: accommodation container
14: transport device
14a: attachment portion
15: transport arm
16: transport device
16a: attachment portion
20: surface defect measurement unit
22, 32: stage
23: incidence unit
24: condenser lens
25, 26: light receiving unit
27: condenser lens
28: calculation unit
29: storage unit
30: analysis section
33: container portion
34: light source unit
35: condenser lens
36: analysis unit
38: carrier gas supply unit
39: pipe
40: cleaning gas supply unit
41: outflow unit
42: control unit
44: plasma torch
46: mass spectrometry unit
46a: Ion lens portion
46b: mass spectrometer unit
47: ion lens
48: reflectron
49: detector
50: semiconductor substrate
50a: surface
51: defect
51a: analysis sample
70: surface defect measurement device
72: mass spectrometry device
C₁, C₂, C₃: rotation axis
H: direction
La: laser light
Ls: incidence rays
V: height direction

What is claimed is:

1. An analysis apparatus that uses positional information of a defect on a surface of a semiconductor substrate, the analysis apparatus comprising:
an analysis section that performs inductively coupled plasma mass spectrometry by irradiating the defect on the surface of the semiconductor substrate with laser light based on the positional information of the defect on the surface of the semiconductor substrate, and collecting an analysis sample obtained by the irradiation using a carrier gas.

2. An analysis apparatus comprising:
a surface defect measurement device that measures presence or absence of a defect on a surface of a semiconductor substrate, and obtains positional information of the defect on the surface of the semiconductor substrate; and
a mass spectrometry device that performs inductively coupled plasma mass spectrometry by irradiating the defect on the surface of the semiconductor substrate with laser light based on the positional information of the defect on the surface of the semiconductor substrate obtained by the surface defect measurement device, and collecting an analysis sample obtained by the irradiation using a carrier gas.

3. The analysis apparatus according to claim 2,
wherein the surface defect measurement device includes a storage unit that stores the positional information.

4. The analysis apparatus according to claim 2,
wherein the surface defect measurement device includes an incidence unit that causes incidence rays to be incident on the surface of the semiconductor substrate, and a light receiving unit that receives radiated rays radiated by reflection or scattering of the incidence rays due to the defect on the surface of the semiconductor substrate.

5. An analysis apparatus comprising:
a surface defect measurement unit that measures presence or absence of a defect on a surface of a semiconductor substrate, and obtains positional information on the surface of the semiconductor substrate for the defect on the surface of the semiconductor substrate; and
an analysis section that performs inductively coupled plasma mass spectrometry by irradiating the defect on the surface of the semiconductor substrate with laser light based on the positional information of the defect on the surface of the semiconductor substrate, and collecting an analysis sample obtained by the irradiation using a carrier gas.

6. The analysis apparatus according to claim 5,
wherein the surface defect measurement unit includes a storage unit that stores the positional information.

7. The analysis apparatus according to claim 5,
wherein the surface defect measurement unit includes an incidence unit that causes incidence rays to be incident on the surface of the semiconductor substrate, and a light receiving unit that receives radiated rays radiated by reflection or scattering of the incidence rays due to the defect on the surface of the semiconductor substrate.

8. The analysis apparatus according to claim 1, further comprising:
a container portion that accommodates the semiconductor substrate that is a measurement target,
wherein an analysis of the semiconductor substrate by the analysis section is performed in the container portion.

9. The analysis apparatus according to claim 8, further comprising:
a cleaning gas supply unit that supplies a cleaning gas to an inside of the container portion; and
an outflow unit that allows the cleaning gas to flow out from the inside of the container portion.

10. The analysis apparatus according to claim 5, further comprising:
an introduction portion in which an accommodation container that accommodates the semiconductor substrate that is a measurement target is installed; and
a transport device that transports the semiconductor substrate from the introduction portion to the surface defect measurement unit.

11. An analysis method in which positional information of a defect on a surface of a semiconductor substrate is used, the analysis method comprising:
a step of performing inductively coupled plasma mass spectrometry by irradiating the defect on the surface of the semiconductor substrate with laser light based on the positional information of the defect on the surface of the semiconductor substrate, and collecting an analysis sample obtained by the irradiation using a carrier gas.

12. An analysis method comprising:
a step of measuring presence or absence of a defect on a surface of a semiconductor substrate, and obtaining positional information on the surface of the semiconductor substrate for the defect on the surface of the semiconductor substrate; and
a step of performing inductively coupled plasma mass spectrometry by irradiating the defect on the surface of the semiconductor substrate with laser light based on the positional information of the defect on the surface of the semiconductor substrate, and collecting an analysis sample obtained by the irradiation using a carrier gas.

13. The analysis method according to claim 11,
wherein the carrier gas has a moisture content being equal to or more than 0.00001 ppm by volume and equal to or less than 0.1 ppm by volume.

14. The analysis method according to claim 11,
wherein the step of performing the inductively coupled plasma mass spectrometry is performed in a container portion that accommodates the semiconductor substrate that is a measurement target, and
the analysis method further comprises a step of cleaning an inside of the container portion with a cleaning gas, which is performed before the step of performing the inductively coupled plasma mass spectrometry.

15. The analysis apparatus according to claim 3,
wherein the surface defect measurement device includes an incidence unit that causes incidence rays to be incident on the surface of the semiconductor substrate, and a light receiving unit that receives radiated rays radiated by reflection or scattering of the incidence rays due to the defect on the surface of the semiconductor substrate.

16. The analysis apparatus according to claim 6,
wherein the surface defect measurement unit includes an incidence unit that causes incidence rays to be incident on the surface of the semiconductor substrate, and a light receiving unit that receives radiated rays radiated by reflection or scattering of the incidence rays due to the defect on the surface of the semiconductor substrate.

17. The analysis apparatus according to claim 5, further comprising:
a container portion that accommodates the semiconductor substrate that is a measurement target,
wherein an analysis of the semiconductor substrate by the analysis section is performed in the container portion.

18. The analysis apparatus according to claim 17, further comprising:
a cleaning gas supply unit that supplies a cleaning gas to an inside of the container portion; and
an outflow unit that allows the cleaning gas to flow out from the inside of the container portion.

19. The analysis apparatus according to claim 6, further comprising:
an introduction portion in which an accommodation container that accommodates the semiconductor substrate that is a measurement target is installed; and
a transport device that transports the semiconductor substrate from the introduction portion to the surface defect measurement unit.

20. The analysis method according to claim 12,
wherein the carrier gas has a moisture content being equal to or more than 0.00001 ppm by volume and equal to or less than 0.1 ppm by volume.
